(19) United States
(12) Patent Application Publication
(10) Pub. No.: US 2026/0253786 A1
(43) Pub. Date: Aug. 27, 2026

(54) COIL BOARD AND MANUFACTURING METHOD THEREOF

(71) Applicant: Zhuhai YUEXIN Semiconductor Limited Liability Company, Guangdong (CN)

(72) Inventors: XIANMING CHEN, Guangdong (CN); WENJIAN LIN, Guangdong (CN); YINGSHAN ZENG, Guangdong (CN); BENXIA HUANG, Guangdong (CN)

(21) Appl. No.: 19/393,874

(22) Filed: Nov. 19, 2025

(30) Foreign Application Priority Data
Feb. 25, 2025 (CN) 2025102168359

(51) Int. Cl. H01F 27/28; H01F 27/32; H01F 41/04; H01F 41/12

(52) U.S. Cl. CPC H01F 27/2804; H01F 27/2871; H01F 27/323; H01F 41/042; H01F 41/122; H01F 2027/2809

(57) ABSTRACT

A coil board includes a first coil, a first plating layer covered on the first coil, a dielectric layer covered on the first plating layer, a second coil on the dielectric layer and a second plating layer covered on the second coil. The first plating layer is located between the dielectric layer and the first coil, the dielectric layer includes a first blind hole, and the second coil is conductively connected to the first coil via the first blind hole. The coil board further includes a first conductive pad disposed in parallel with the first coil and a second conductive pad disposed in parallel with the second coil. The dielectric layer includes a second blind hole, and the second conductive pad is conductively connected to the first conductive pad via the second blind hole.

### CROSS-REFERENCE TO RELATED APPLICATION AND CLAIM OF PRIORITY

This application claims the benefit under 35 USC § 119 of Chinese Patent Application No. 2025102168359, filed on Feb. 25, 2025 in the China Intellectual Property Office, the entire disclosure of which is incorporated herein by reference for all purposes.

### BACKGROUND

### 1. Technical Field

The present disclosure relates to the technical field of packaging, and more particularly, to a coil board and a manufacturing method thereof.

### 2. Background Art

Voice coil motor (VCM) has the characteristics of high frequency response and high precision. Optical image stabilization (OIS) system is a kind of VCM, which is widely used in camera to achieve auto-focus function for showing a clear image by adjusting the position of the lens. The coil board is applied to VCM-OIS of camera, which is designed to realize anti-shake stabilization by forcing the lens or sensor to move in the magnetic field by means of coil.

As lens modules become more complex, the weight tends to increase, as does the force required to move the lens or sensor. According to the force formula F=BIL (in the formula, B is the magnetic field strength, I is the current, and L is the wire length) of the electrified wire in the magnetic field, Ohm's law I=U/R (in the formula, U is the voltage, and R is the resistance), and the wire resistance formula R=ρL/S (in the formula, ρ is the resistivity of the material by which the resistance is made, L is the length of wire by which the resistance is made, and S is the cross-sectional area of the wire by which the resistance is made), so F=BUS/ρ can be derived. Obviously, in the case where the magnetic field strength B, the voltage U, and the resistivity ρ of the material are fixed values, increasing the pushing force can be achieved by increasing the cross-sectional area S of the wire. However, with regard to the technical solution of increasing the cross-sectional area S, there is a significant deficiency in the related art.

### SUMMARY

In view of the above, it is an object of the present disclosure to provide a coil board and a manufacturing method thereof.

In view of the above object, in a first aspect, the present disclosure provides a coil board, comprising a first coil, a first plating layer covered on the first coil, a dielectric layer covered on the first plating layer, a second coil on the dielectric layer and a second plating layer covered on the second coil; wherein the first plating layer is located between the dielectric layer and the first coil, the dielectric layer includes a first blind hole, and the second coil is conductively connected to the first coil via the first blind hole; wherein the coil board further includes a first conductive pad disposed in parallel with the first coil and a second conductive pad disposed in parallel with the second coil; wherein the dielectric layer includes a second blind hole, and the second conductive pad is conductively connected to the first conductive pad via the second blind hole.

In some embodiments, it further includes a solder mask layer, wherein the solder mask layer is covered on the second plating layer and the dielectric layer; wherein the solder mask layer includes a solder mask opening to expose at least a portion of the second plating layer.

In some embodiments, the first conductive pad is covered with the first plating layer; and/or the second conductive pad is covered with the second plating layer.

In some embodiments, the first conductive pad and the second conductive pad are located in a non-product area of the coil board.

In a second aspect, the embodiments of the present disclosure also provide a method for manufacturing a coil board, comprising:
(a) preparing a bearing board;
(b) forming a first coil and a first conductive pad on the bearing board;
(c) electroplating on an entire surface to form a first plating layer covered on the first coil and the first conductive pad;
(d) pressing a dielectric layer on the first plating layer and providing a first blind hole and a second blind hole; wherein the first blind hole exposes the first plating layer provided on the first coil; and the second blind hole exposes the first plating layer provided on the first conductive pad;
(e) forming a second coil and a second conductive pad on the dielectric layer; wherein the second coil is conductively connected to the first coil via the first blind hole; and the second conductive pad is conductively connected to the first conductive pad via the second blind hole;
(f) electroplating a second plating layer on the second coil and the second conductive pad; wherein the first conductive pad and the second conductive pad are located in a non-product area; and
(g) removing the bearing board.

In some embodiments, it further comprises:
(h) forming a solder mask layer on the dielectric layer; wherein the solder mask includes a solder mask opening to expose at least a portion of the second plating layer.

In some embodiments, the step (b) specifically includes:
(b1) the bearing board including a support layer and a first seed layer on the support layer, and forming a first photoresist layer on the first seed layer and patterned;
(b2) electroplating in the pattern of the first photoresist layer to form a first coil and a first conductive pad; and
(b3) removing the first photoresist layer.

In some embodiments, the material of the first seed layer is copper;
the step (b) further includes: forming a first metal layer on the first seed layer, and forming a first coil and a first conductive pad on the first metal layer; wherein the first metal layer includes a non-copper metal; and
the step (c) further includes: after etching the exposed first metal layer, electroplating on an entire surface to form a first plating layer covered on the first coil and the first conductive pad.

In some embodiments, the step (g) further includes etching the first metal layer remaining on the first coil and the first conductive pad.

In some embodiments, the non-copper metal is selected from at least one of titanium (Ti), chromium (Cr), tungsten (W), zirconium (Zr), aluminum (Al), silver (Ag), or gold (Au).

In some embodiments, the step (e) includes:
(e1) electroless copper plating on the dielectric layer;
(e2) forming a second photoresist layer on the dielectric layer and patterning the same;
(e3) forming a second coil and a second conductive pad by electroplating in the pattern of the second photoresist layer; and
(e4) removing the second photoresist layer.

In some embodiments, the bearing board further includes a copper foil layer; the copper foil layer is located between the support layer and the first seed layer; the copper foil layer and the first seed layer are physically bonded; and
the step (g) includes separating the copper foil layer and the first seed layer to remove the bearing board.

It can be seen from the above that the present disclosure provides a coil board and a manufacturing method thereof. The technical effect of increasing the pushing force of the coil board is achieved by adding a first plating layer and a second plating layer, increasing the cross-sectional area of a first coil by using the first plating layer, and increasing the cross-sectional area of a second coil by using the second plating layer. The technical effect of electroplating the second plating layer on an isolated second coil is achieved by using the first and second conductive pads, and also, the first and second conductive pads are formed in a non-working area without removing, thus saving the process. The first metal layer formed from a non-copper metal protects the bottom surface of the first coil, so that the subsequent etching to remove the exposed first seed layer and first plating layer does not attack the first coil, preventing the first coil from thinning in cross-section.

### BRIEF DESCRIPTION OF THE DRAWINGS

In order to explain the technical solution of the present disclosure or the related art more clearly, a brief introduction will be made to the accompanying drawings which are required to be used in the description of the embodiments or the related art. It is obvious that the drawings in the description below are merely embodiments of the present disclosure. It is possible for a person of ordinary skill in the art to obtain other drawings according to the drawings without involving any inventive effort.

FIG. 1 is a schematic diagram showing an intermediate structure of a coil board provided in the related art;

FIGS. 2A to 2R are schematic cross-sectional or front views of an intermediate structure at various steps of a method for manufacturing a coil board according to an embodiment of the present disclosure;

FIG. 3 is a structurally schematic view of a coil board according to an embodiment of the present disclosure.

### DETAILED DESCRIPTION OF THE EMBODIMENTS

The purpose, aspects, and advantages of the present disclosure will become more apparent from the detailed description set forth below when taken in conjunction with the specific embodiments and with reference to the drawings.

It should be noted that, unless otherwise defined, technical or scientific terms used in the embodiments of the present disclosure shall have the ordinary meaning as understood by one of ordinary skill in the art to which this invention belongs. The use of “first”, “second”, and the like in the embodiments of the present disclosure does not denote any order, quantity, or importance, but rather is used to distinguish one element from another. The word “comprising” or “comprises”, and the like, is intended to cover the presence of elements or items preceding the word, including the elements or items listed after the word, and equivalents thereof, without excluding other elements or items. The terms “connected” or “coupled” and the like are not limited to physical or mechanical connections, but may include electrical connections, whether direct or indirect connections. When terms such as “upper”, “above”, “below”, and “beside” are used to describe a positional relationship between two elements, one or more of the components may be located between the two components unless these terms are used in conjunction with the terms “immediately” or “directly”. When an element or layer is “disposed on” another element or layer, the other layer or element can be directly interposed on or between the other elements. In the drawings, the thickness and shape of some of the layers and regions may be exaggerated for better understanding and ease of description. A component is to be construed as including a generic range of error even if not explicitly described.

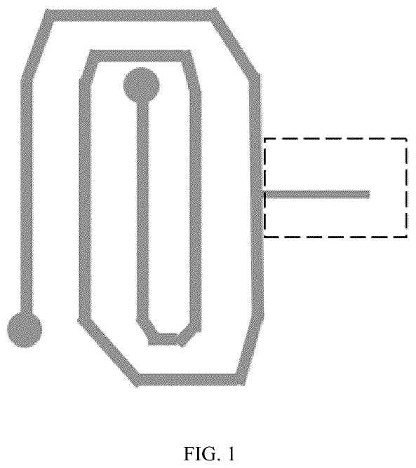

There is no indication in the prior art of how to increase the coil cross-sectional area in order to increase coil thrust. Also, with regard to the problem of coil plating, as shown in FIG. 1, the relevant art discloses that a temporary plating lead is made on a coil (within a dotted line frame in FIG. 1), and the temporary plating lead is used as an electrical conduction path during plating, and then the temporary plating lead is removed to avoid a short circuit. The solutions in the prior art increase the process complexity and design difficulty.

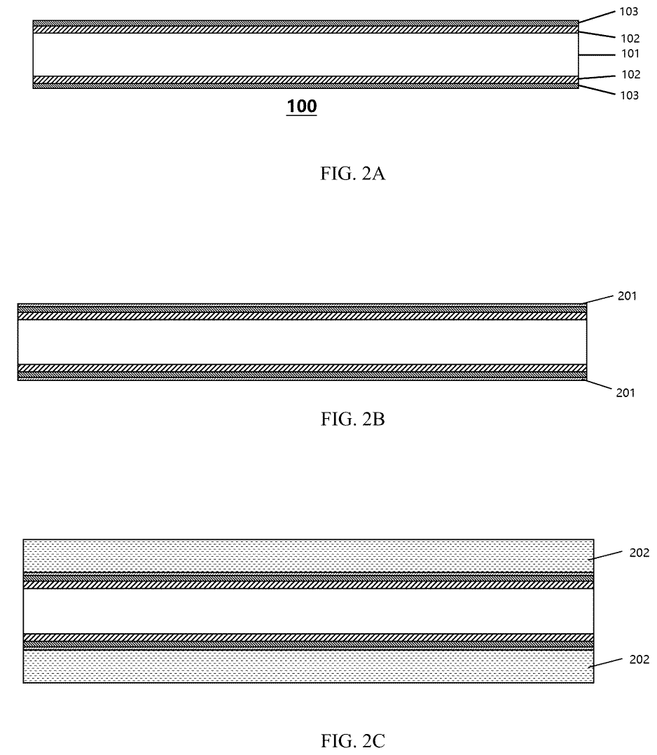

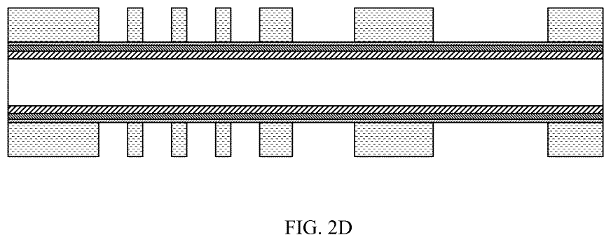

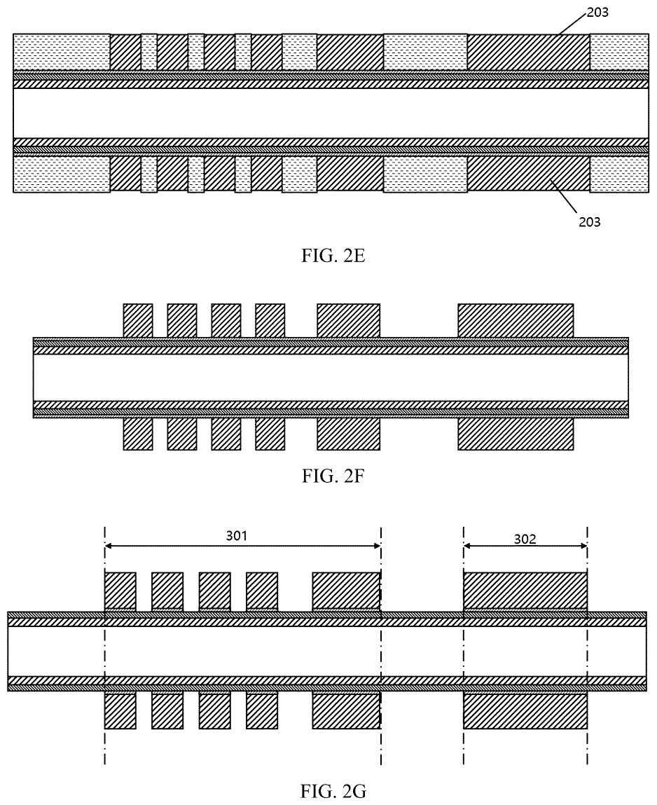

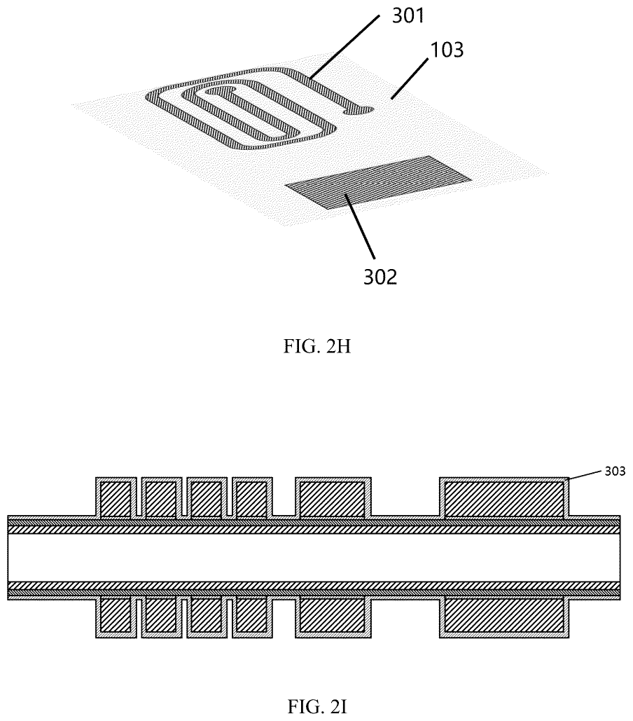

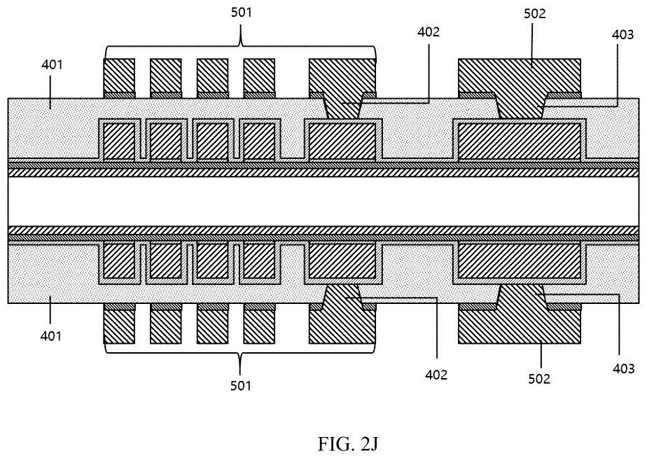

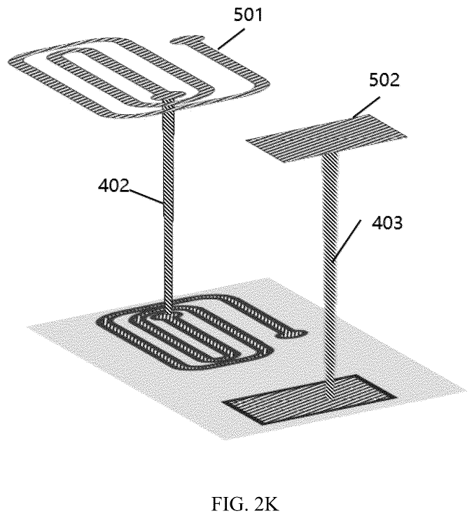

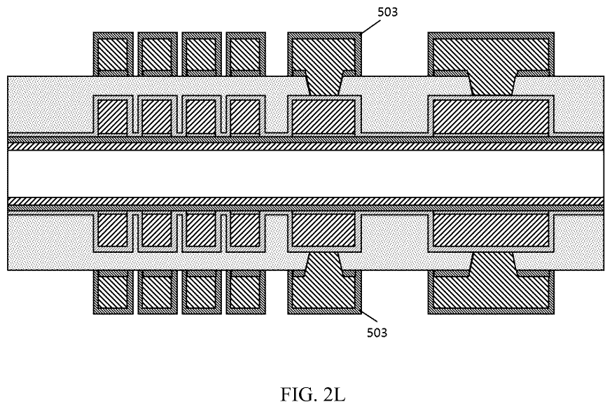

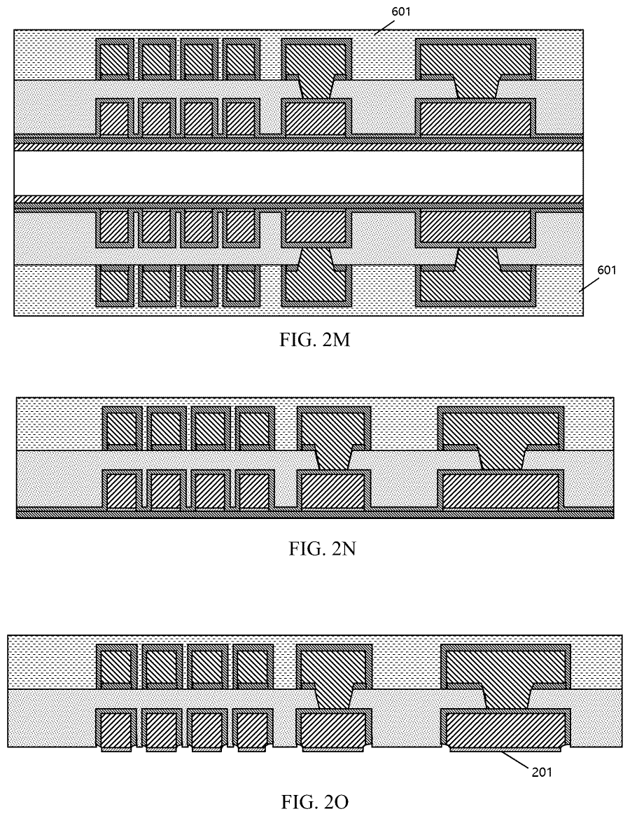

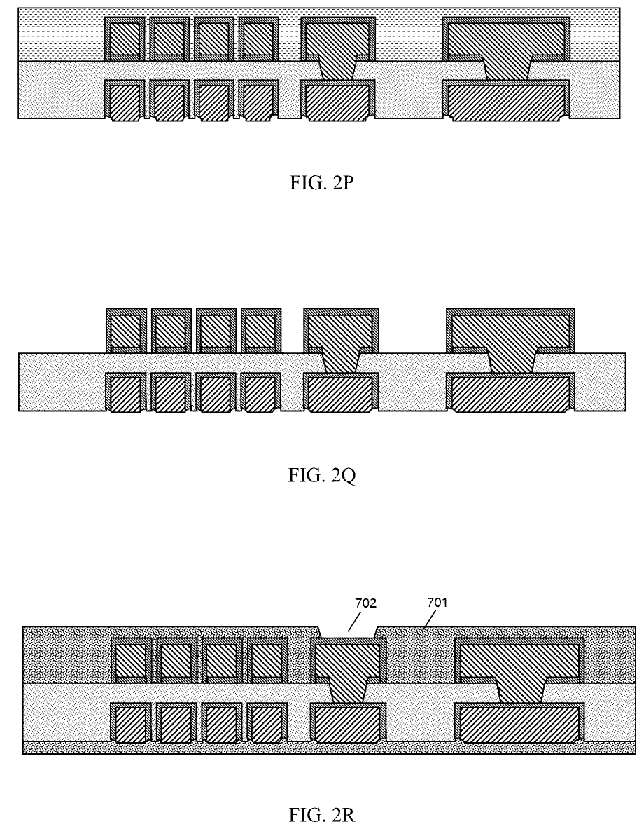

In view of the above, embodiments of the present disclosure provide a method for manufacturing a coil board. FIGS. 2A to 2R are schematic cross-sectional or front views of an intermediate structure at various steps of a method for manufacturing a coil board according to an embodiment of the present disclosure. As shown in FIGS. 2A to 2R, the manufacturing method includes the steps below.

Firstly, a bearing board 100 is provided in a step (a), as shown in FIG. 2A

In some embodiments, the bearing board 100 further includes a support layer 101, a first seed layer 103, and a copper foil layer 102 therebetween. Here, the copper foil layer 102 and the first seed layer 103 are physically bonded, and can be physically separated.

Alternatively, the material of the support layer 101 includes, but is not limited to, resin, fiberglass, glass, silicon, metal. The first seed layer 103 and the copper foil layer 102 are provided on one side or both sides of the support layer 101. It should be understood that the bearing board 100 may also include more strippable metal conductive layers, such as copper foil, and the present disclosure is not limited in this regard.

Optionally, the copper foil layer 102 has a thickness of 16-20 μm, e. g., 18 μm. Alternatively, the first seed layer 103 may be a copper foil of 1.5-5 μm.

Next, as shown in FIG. 2B, a first metal layer 201 is formed on the first seed layer 103. The first metal layer 201 includes, among other things, a non-copper metal. Here, the non-copper metal includes at least one of titanium (Ti), chromium (Cr), tungsten (W), zirconium (Zr), aluminum (Al), silver (Ag), or gold (Au).

Optionally, the first metal layer 201 may also include copper. It should be noted that the copper should now be on a side of the first metal layer 201 away from the bearing board 100.

Alternatively, the first metal layer 201 can be formed by sputtering or electroplating, for example, sputtering titanium first and then sputtering copper on the first seed layer 103. As another example, the first seed layer 103 is electroboarded with titanium followed by electroboarded with copper.

Note that the step of forming the first metal layer 201 may be omitted.

Then, a first coil 301 and a first conductive pad 302 are formed on the first metal layer 201 in the step (b), as shown in FIGS. 2C to 2G.

It should be understood that if the step of forming the first metal layer 201 is omitted, the first coil 301 and the first conductive pad 302 are formed on the first seed layer 103.

In some embodiments, the step (b) specifically includes the steps below.
(b1) A first photoresist layer 202 is formed and patterned on the first metal layer 201, as shown in FIG. 2C and FIG. 2D. Here, the patterning is achieved by exposing and developing to show the position of the first wiring layer.

Note that if the step of forming the first metal layer 201 is omitted, the first photoresist layer 202 is formed and patterned on the first seed layer 103, which will not be described in detail in the present disclosure.
(b2) A first wiring layer 203 is boarded in the pattern of the first photoresist layer 202, as shown in FIG. 2E. Here, the first wiring layer 203 partially forms a first coil 301 and partially forms a first conductive pad 302. The material of the first wiring layer 203 may be copper.
(B3) The first photoresist layer 202 is removed, as shown in FIG. 2F.
(b4) The first metal layer 201 not covered by the first wiring layer 203 is etched, as shown in FIG. 2G and FIG. 2H. It should be understood that the first metal layer 201 may be etched by using a liquid medicine that etches a particular metal, and thus the liquid medicine should correspond to the material of the first metal layer 201. The present disclosure is not limited thereto. If the step of forming the first metal layer 201 is omitted, the step (b4) may be omitted.

After the step (b), as apparent from FIG. 2H, the first coil 301 and the first conductive pad 302 are formed on the first seed layer 103. It should be noted that the first conductive pad 302 is located in a non-product area, i. e., a waste area.

In this manner, no additional processing of the first conductive pad 302 is required after the final product is completed, which helps to reduce the number of manufacturing processes.

Next, the entire surface is boarded to form a first plating layer 303 covered on the first coil 301, the first conductive pad 302, and the first seed layer 103 in the step (c), as shown in FIG. 2I. Here, the material of the first plating layer 303 may be copper.

Then, a dielectric layer 401 is laminated on the first plating layer 303, and a first blind hole 402 and a second blind hole 403 are provided. The first blind hole 402 exposes a first plating layer on a part of the first coil 301. The second blind via 403 exposes a first plating layer on a part of the first conductive pad 302 in the step (d), with reference to FIG. 2J.

Alternatively, the material of the dielectric layer 401 may be a resin material such as one selected from the group consisting of a liquid crystal polymer, a BT (bismaleimide triazine) resin, a prepreg, a Ajinomoto Build-up Film (ABF), an epoxy resin, and a polyimide resin. However, the present disclosure is not limited thereto.

The first blind hole 402 and the second blind hole 403 can be opened by means of laser drilling, laser drilling, etc., and the present disclosure does not limit this.

In some alternative embodiments, the dielectric layer 401 and the second seed layer are laminated at the first plating layer 303, thereby saving the step of fabricating the second seed layer.

Next, a second coil 501 and a second conductive pad 502 are formed on the dielectric layer 401 in the step (e), as shown in FIGS. 2J and 2K. Here, the second coil 501 is conductively connected to the first coil 301 via the first blind hole 402. The second conductive pad 502 is conductively connected to the first conductive pad 302 via the second blind hole 403.

It should be noted that the second conductive pad 502 is located in a non-product area, i. e., a waste area. In this manner, no additional processing of the second conductive pad 502 is required after the final product is completed, which helps to reduce the manufacturing process.

In some embodiments, the step (e) includes the steps below.
(e1) De-smearing and chemical copper plating (PHT) are performed.

Here, the de-smearing treatment can remove organic residues remaining on the first blind hole 402 and the second blind hole 403, which helps ensure that the second coil 501 is conductively connected to the first coil 301 via the first blind hole 402. The second conductive pad 502 is conductively connected to the first conductive pad 302 by the second blind hole 403 so as to avoid a virtual connection.

The electroless copper plating may form a copper layer on the sidewalls and bottom of the first blind hole 402 and the second blind hole 403 to facilitate subsequent plating.
(e2) A second photoresist layer is formed and patterned on the dielectric layer 401.
(e3) A second coil 501 and a second conductive pad 502 are formed by electroplating at the hollowed-out part of the pattern of the second photoresist layer.
(e4) The second photoresist layer is removed.
(e5) The second seed layer is flash etched.

Here, the steps (e2) to (e4) are similar to the steps (b1) to (b3) and will not be described in detail.

Then, a second plating layer 503 is boarded on the second coil 501 and the second conductive pad 502 in the step (f), as shown in FIG. 2L. Here, the first coil 301 and the first conductive pad 302 are formed on the surface of the first seed layer 103, so that they can electrically conduct the whole. The second coil 501 conducts the first coil 301, the first seed layer 103 and the first conductive pad 302 via a first blind hole. The second conductive pad 502 conducts the first conductive pad 302 via a second blind hole. The second conductive pad 502 is used for connecting to an external electrode to form an electrical loop.

In the electroplating, the second conductive pad 502 only needs to be connected to an external electrode to form an electrical loop, so as to achieve the purpose of plating an isolated second coil 501, and there is no need to pull a plating lead on the second coil 501, which contributes to improving the complicated plating process.

Next, a third photoresist layer 601 is formed on the dielectric layer 401 and the second plating layer 503, as shown in FIG. 2M. The third photoresist layer 601 is used to protect the first coil 301 and the second coil 501 from scratching, and to prevent the first coil 301 and the second coil 501 from being attacked by the subsequent etching.

The support layer 101 is then removed the step (g), as shown in FIG. 2N. Specifically, the support layer 101 can be easily removed by peeling off the copper foil layer 102 and the first seed layer 103.

Next, the first seed layer 103 and the first plating layer 303 located on the surface of the dielectric layer 401 on a side away from the second coil 501 and the second conductive pad 502 are etched, as shown in FIG. 2O.

Here, the first plating layer 303 located on the surface of the dielectric layer 401 is etched to ensure that the first coil 301 is in a non-short circuit state.

Since the material of the surface of the first metal layer 201 is different from copper, it is not dissolved in a solution for etching copper, so that the first coil 301 can be protected from over-etching, ensuring that the cross-sectional area of the first coil 301 is not greatly reduced.

As shown in FIG. 2P, etching the first metal layer 201 located on the first coil 301 and the first conductive pad 302 is also included. The material of the first coil 301 and the first conductive pad 302 is copper, and the etching solution for etching the first metal layer 201 does not dissolve copper, so that the first coil 301 can be effectively prevented from being attacked.

It should be understood that, if the step of forming the first metal layer 201 is omitted, it is difficult to ensure that the first coil 301 does not erode when etching the first seed layer 103 and the first plating layer 303, thereby making it disadvantageous to maximize the cross-sectional area of the first coil 301. Even so, the manufacturing method provided by the embodiments of the present disclosure can still increase the cross-sectional area of the first coil 301 by using the first plating layer.

Then, the third photoresist layer is removed, as shown in FIG. 2Q.

Finally, a solder mask layer 701 is formed on the dielectric layer 401. The solder mask layer 701 includes a solder mask opening 702 to expose at least a portion of second plating layer 503 in the step (i), as shown in FIG. 2R.

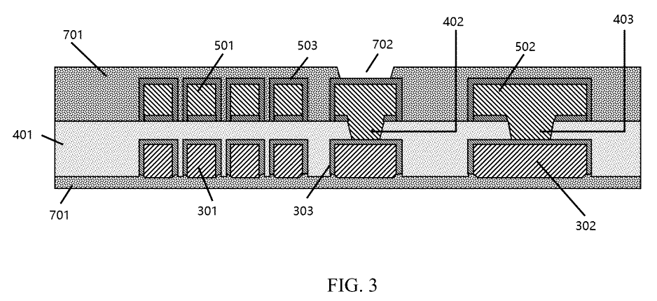

As shown in FIG. 3, embodiments of the present disclosure also provide a coil board. As shown in FIG. 3, the coil board includes a dielectric layer 401, a first coil 301, a second coil 501, a first plating layer 303 and a second plating layer 503. The first coil 301 is disposed in the dielectric layer 401, and the first plating layer 303 is located between the dielectric layer 401 and the first coil 301. A second coil 501 is disposed on the dielectric layer 401. The dielectric layer 401 includes a first blind hole 402, and the second coil 501 is conductively connected to the first coil 301 via the first blind hole 402. The second coil 501 is provided with a second plating layer 503. By providing the first coil 301 and the second coil 501 with the first plating layer 303 and the second plating layer 503, respectively, the effect of increasing the thrust force of the coil board is achieved.

In some embodiments, it further includes a solder mask layer 701. The solder mask layer 701 is disposed on the surface of the dielectric layer 401. The solder mask layer 701 includes a solder mask opening 702 to expose at least a portion of second plating layer 503.

In some embodiments, it further includes a first conductive pad 302 and a second conductive pad 502. The first conductive pad 302 is disposed in the dielectric layer 401 in parallel with the first coil 301. The dielectric layer 401 includes a second blind hole 403. The second conductive pad 502 parallel to the second coil 501 is disposed on the dielectric layer 401 and is conductively connected to the first conductive pad 302 via the second blind hole 403.

Plating of the second coil 501 to increase the cross-sectional area of the second coil 501 can be conveniently accomplished by using the second conductive pad 502.

In some embodiments, a first plating layer 303 is disposed between the dielectric layer 401 and the first conductive pad 302; and/or a second plating layer 503 is disposed on the second conductive pad 502.

In some embodiments, the first conductive pad 302 and the second conductive pad 502 are located in a non-product area of the coil board. Disposing the first conductive pad 302 and the second conductive pad 502 in the non-product area does not require additional processing, which helps to reduce the manufacturing process.

Those of ordinary skill in the art will appreciate that the discussion of any embodiment above is intended to be exemplary only, and is not intended to suggest that the scope of the disclosure, including the claims, is limited to these examples. The combinations of the features in the above embodiments or in different embodiments may also be made within the concept of the disclosure, the steps may be implemented in any order, and there are many other variations of the different aspects of the embodiments of the disclosure as described above, which are not provided in detail for the sake of clarity.

The disclosed embodiments are intended to embrace all such alternatives, modifications and variances that fall within the broad scope of the appended claims. Accordingly, it is intended that the present disclosure embrace all such alternatives, modifications, equivalents, and improvements as fall within the spirit and broad scope of the disclosed embodiments.

What is claimed is:

1. A coil board comprising:
a first coil;
a first plating layer covered on the first coil;
a dielectric layer covered on the first plating layer;
a second coil on the dielectric layer;
a second plating layer covered on the second coil;
a first conductive pad disposed in parallel with the first coil; and
a second conductive pad disposed in parallel with the second coil,
wherein the first plating layer is located between the dielectric layer and the first coil,
the second coil is conductively connected to the first coil via the first blind hole,
the dielectric layer includes a first blind hole and a second blind hole, and
the second conductive pad is conductively connected to the first conductive pad via the second blind hole.

2. The coil board according to claim 1, further comprising:
a solder mask layer covered on the second plating layer and the dielectric layer, the solder mask layer comprising a solder mask opening to expose at least a portion of the second plating layer.

3. The coil board according to claim 1, wherein the first conductive pad is covered with the first plating layer; and/or
the second conductive pad is covered with the second plating layer.

4. The coil board according to claim 1, wherein the first conductive pad and the s econd conductive pad are located in a non-product area of the coil board.

5. A method for manufacturing a coil board, the method comprising:
(a) preparing a bearing board;
(b) forming a first coil and a first conductive pad on the bearing board;
(c) electroplating on an entire surface to form a first plating layer covered on the first coil and the first conductive pad;
(d) pressing a dielectric layer on the first plating layer and providing a first blind hole and a second blind hole; wherein the first blind hole exposes the first plating layer provided on the first coil; and the second blind hole exposes the first plating layer provided on the first conductive pad;
(e) forming a second coil and a second conductive pad on the dielectric layer, wherein the second coil is conductively connected to the first coil via the first blind hole, and the second conductive pad is conductively connected to the first conductive pad via the second blind hole;
(f) electroplating a second plating layer on the second coil and the second conductive pad, wherein the first conductive pad and the second conductive pad are located in a non-product area; and
(g) removing the bearing board.

6. The manufacturing method according to claim 5, further comprising:
(h) forming a solder mask layer on the dielectric layer, wherein the solder mask comprises a solder mask opening to expose at least a portion of the second plating layer.

7. The manufacturing method according to claim 5, wherein the step (b) comprises
(b1) the bearing board comprising a support layer and a first seed layer on the support layer, and forming a first photoresist layer on the first seed layer and patterned;
(b2) electroplating in the pattern of the first photoresist layer to form a first coil and a first conductive pad; and
(b3) removing the first photoresist layer.

8. The manufacturing method according to claim 7, wherein the material of the first seed layer is copper;
the step (b) further comprises forming a first metal layer on the first seed layer, and forming a first coil and a first conductive pad on the first metal layer; wherein the first metal layer comprises a non-copper metal; and
the step (c) further comprises: after etching the exposed first metal layer, electroplating on an entire surface to form a first plating layer covered on the first coil and the first conductive pad.

9. The manufacturing method according to claim 8, wherein the step (g) further comprises:
etching the first metal layer remaining on the first coil and the first conductive pad.

10. The manufacturing method according to claim 8, wherein the non-copper metal is selected from at least one of titanium, chromium, tungsten, zirconium, aluminum, silver, or gold.

11. The manufacturing method according to claim 5, wherein the step (e) comprises:
(e1) electroless copper plating on the dielectric layer;
(e2) forming a second photoresist layer on the dielectric layer and patterning the same;
(e3) forming a second coil and a second conductive pad by electroplating in the pattern of the second photoresist layer; and
(e4) removing the second photoresist layer.

12. The manufacturing method according to claim 7, wherein the bearing board further comprises a copper foil layer; the copper foil layer is located between the support layer and the first seed layer; the copper foil layer and the first seed layer are physically bonded; and
the step (g) comprises separating the copper foil layer and the first seed layer to remove the bearing board.
